(19) United States
(12) Patent Application Publication
(10) Pub. No.: US 2014/0191192 A1
(43) Pub. Date: Jul. 10, 2014

(54) SEMICONDUCTOR LIGHT-EMITTING DEVICE

(71) Applicants: Sang Heon Han, Suwon-si (KR); Hyun Wook Shim, Suwon-si (KR); Je Won Kim, Seoul (KR); Chu Young Cho, Gwangju (KR); Seong Ju Park, Gwangju (KR); Sung Tae Kim, Seoul (KR); Jin Tae Kim, Seongnam-si (KR); Yong Chun Kim, Yongin-si (KR); Sang Jun Lee, Gwangju (KR)

(72) Inventors: Sang Heon Han, Suwon-si (KR); Hyun Wook Shim, Suwon-si (KR); Je Won Kim, Seoul (KR); Chu Young Cho, Gwangju (KR); Seong Ju Park, Gwangju (KR); Sung Tae Kim, Seoul (KR); Jin Tae Kim, Seongnam-si (KR); Yong Chun Kim, Yongin-si (KR); Sang Jun Lee, Gwangju (KR)

(73) Assignee: SAMSUNG ELECTRONICS CO., LTD., Suwon-si, Gyeonggi-do (KR)

(21) Appl. No.: 14/235,705

(22) PCT Filed: Jul. 29, 2011
(86) PCT No.: PCT/KR2011/005586

§ 371 Date: Jan. 28, 2014

(51) Int. Cl. H01L 33/00; H01L 33/06

(52) U.S. Cl. CPC H01L 33/0025; H01L 33/06
USPC 257/13

(57) ABSTRACT

There is provided a semiconductor light emitting device having improved light emitting efficiency by increasing an inflow of holes into an active layer while preventing an overflow of electrons. The semiconductor light emitting device includes an n-type semiconductor layer; an active layer formed on the n-type semiconductor layer and including at least one quantum well layer and at least one quantum barrier layer alternately stacked therein; an electron blocking layer formed on the active layer and having at least one multilayer structure including three layers having different energy band gaps stacked therein, a layer adjacent to the active layer among the three layers having an inclined energy band structure; and a p-type semiconductor layer formed on the electron blocking layer.

### TECHNICAL FIELD

The present disclosure relates to a semiconductor light emitting device, and more particularly, to a semiconductor light emitting device having improved light emitting efficiency through allowing an inflow of holes into an active layer to be increased, while an overflow of electrons is prevented.

### BACKGROUND

Recently, nitride semiconductors, such as GaN and the like, have been prominent as core materials for light emitting devices such as light emitting diodes (LEDs) or laser diodes (LDs) due to superior physical and chemical properties thereof. Such nitride semiconductors are typically formed of a semiconductor material having a composition expressed by InₓAl_{y}Ga_{1-x-y}N, where 0≦x≦1, 0≦y≦1, 0≦x+y≦1. Light emitting diodes (LEDs) or laser diodes (LDs) using nitride semiconductor materials are being used in light emitting devices emitting light having a blue or green wavelength band and are being used as light sources in various products, such as keypad light emitting diodes in mobile phones, electrical sign boards, and general lighting devices.

Subsequently to the development of nitride LEDs, technical advances were achieved, which extensively broadened the range of applications of nitride LEDs, and research into the use of nitride LEDs as light sources for lighting devices and vehicles is being actively conducted. In particular, nitride LEDs have conventionally been adopted as components in low current/low output mobile products; however, in recent years, the use of nitride LEDs has been extended into the field of high current/high output products, and thus, high levels of luminance and reliability are required therein.

Under these circumstances, various methods for improving light emitting efficiency in nitride light emitting devices are being researched. One such method is to use an electron blocking layer. Such an electron blocking layer is usually provided between an active layer and a p-type semiconductor layer in a general light emitting device structure. The electron blocking layer is employed to improve carrier recombination efficiency within the active layer by preventing electrons having a relatively higher degree of mobility than holes from overflowing into the p-type semiconductor layer. However, such an electron blocking layer may serve as a blocking layer with respect to the holes as well as to the electrons. Therefore, an inflow of the holes into the active layer may be affected by the electron blocking layer, and the concentration of the holes in the active layer may be reduced.

### DISCLOSURE

### Technical Problem

An aspect of the present disclosure provides a semiconductor light emitting device capable of increasing an inflow of holes into an active layer while blocking an overflow of electrons into a p-type semiconductor layer.

### Technical Solution

According to an aspect of the present disclosure, there is provided a semiconductor light emitting device including: an n-type semiconductor layer; an active layer formed on the n-type semiconductor layer and including at least one quantum well layer and at least one quantum barrier layer alternately stacked therein; an electron blocking layer formed on the active layer and having at least one multilayer structure including three layers having different energy band gaps stacked therein, a layer adjacent to the active layer among the three layers having an inclined energy band structure; and a p-type semiconductor layer formed on the electron blocking layer.

The electron blocking layer may be formed of a semiconductor material having a composition expressed by InₓAl_{y}Ga_{1-x-y}N, where 0≦x≦1, 0≦y≦1, 0≦x+y≦1, and the individual layers in the multilayer structure of the electron blocking layer may have different energy band gaps by adjusting a ratio between Al and In. The individual layers in the multilayer structure of the electron blocking layer may be sequentially stacked to allow the energy band gaps thereof to be decreased in a stacking direction.

The electron blocking layer may have a sequentially stacked structure of AlGaN/GaN/InGaN layers. The electron blocking layer may have the stacked structure of AlGaN/GaN/InGaN layers repetitively stacked therein. The electron blocking layer may have a sequentially stacked structure of AlGaN/GaN/InGaN/GaN layers. The electron blocking layer may have the stacked structure of AlGaN/GaN/InGaN/GaN layers repetitively stacked therein. The electron blocking layer may have a superlattice structure, and the individual layers of the electron blocking layer may have a thickness of 0.5 nm to 20 nm.

The layer, adjacent to the active layer, among the three layers included in the multilayer structure of the electron blocking layer, may have an energy band gap, an inclination of which is increased in a stacking direction. The layer, adjacent to the active layer, among the three layers included in the multilayer structure of the electron blocking layer, may have an energy band gap higher than that of the active layer, while allowing an inclination of the energy band gap to be decreased in a stacking direction.

The semiconductor light emitting device may further include an insulating substrate formed on a lower surface of the n-type semiconductor layer; an n-type electrode formed on the n-type semiconductor layer exposed by removing portions of the active layer and the p-type semiconductor layer; and a p-type electrode formed on the p-type semiconductor layer.

The semiconductor light emitting device may further include a conductive substrate formed on the p-type semiconductor layer; and an n-type electrode formed on the n-type semiconductor layer.

### ADVANTAGEOUS EFFECTS

According to embodiments of the inventive concept, while an electron overflow phenomenon is prevented, hole injection efficiency into an active layer may be improved. In particular, light emitting efficiency at high current density may be improved.

### BRIEF DESCRIPTION OF THE DRAWINGS

FIG. 1 is a side cross-sectional view of a semiconductor light emitting device according to a first embodiment of the present disclosure;

FIG. 2 is an energy band gap diagram of the semiconductor light emitting device of FIG. 1;

FIG. 3 is an energy band gap diagram of the semiconductor light emitting device of FIG. 1 including another example of an electron blocking layer;

FIG. 4 is an energy band gap diagram of the semiconductor light emitting device of FIG. 1 including another example of an electron blocking layer;

FIG. 5 is a side cross-sectional view of a semiconductor light emitting device according to a second embodiment of the present disclosure;

FIG. 6 is a graph illustrating simulation results in terms of light emitting efficiency of a semiconductor light emitting device according to an embodiment of the present disclosure and a semiconductor light emitting device including an electron blocking layer having a general superlattice structure; and

FIGS. 7 through 9 are energy band gap diagrams of semiconductor light emitting devices according to a third embodiment of the present disclosure.

### DETAILED DESCRIPTION OF THE EMBODIMENTS

Embodiments of the present disclosure will now be described in detail with reference to the accompanying drawings. The inventive concept disclosed herein may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art. In the drawings, the shapes and dimensions of elements may be exaggerated for clarity, and the same reference numerals will be used throughout to designate the same or like elements.

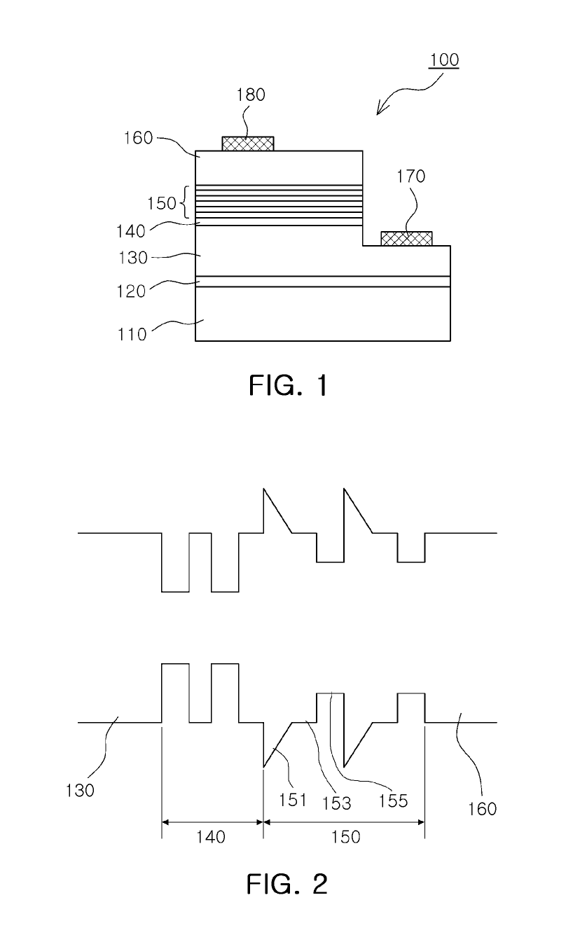

FIG. 1 is a side cross-sectional view of a semiconductor light emitting device according to a first embodiment of the present disclosure, and FIG. 2 is an energy band gap diagram of the semiconductor light emitting device of FIG. 1.

As illustrated in FIG. 1, a semiconductor light emitting device 100 according to the first embodiment may include a substrate 110, a buffer layer 120, an n-type semiconductor layer 130, an active layer 140, an. electron blocking layer 150 and a p-type semiconductor layer 160. An n-type electrode 170 may be formed on an exposed surface of the n-type semiconductor layer 130, and a p-type electrode 180 may be formed on an upper surface of the p-type semiconductor layer 160. Although not illustrated, an ohmic-contact layer formed of a transparent electrode material or the like may be further provided between the p-type semiconductor layer 160 and the p-type electrode 180.

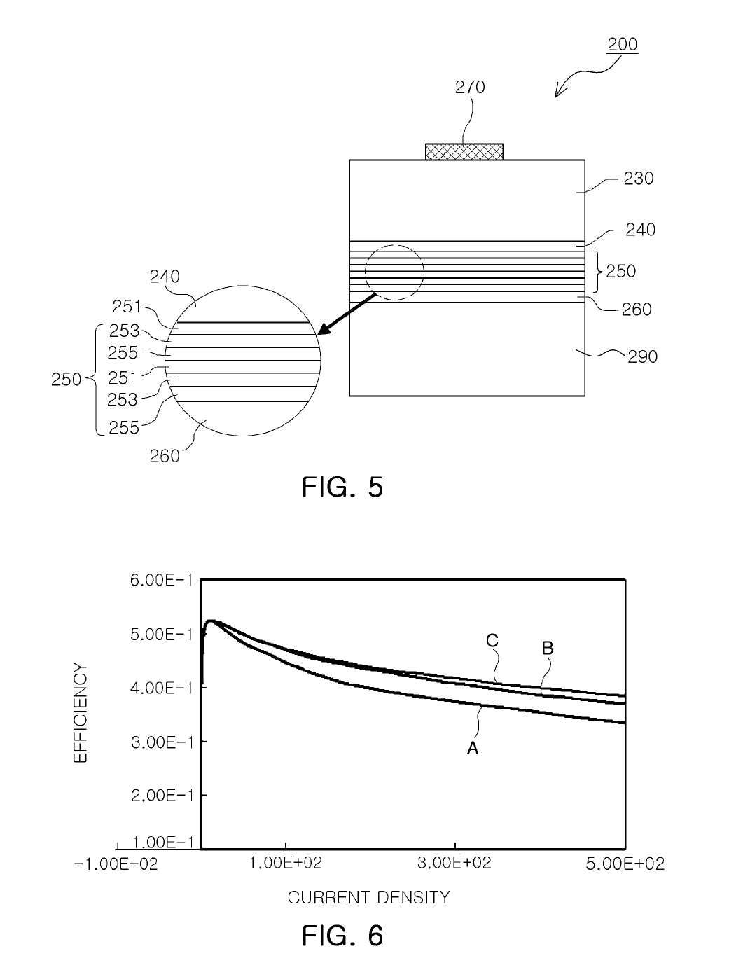

In the present embodiment, the semiconductor light emitting device is exemplified as having a horizontal electrode structure in which the n-type and p-type electrodes 170 and 180 are disposed in the same direction; however, the inventive concept is not limited thereto, and the semiconductor light emitting device may have a vertical electrode structure, which will be described with reference to FIG. 5.

The substrate 110 may be a substrate for growing a nitride single crystal, and a sapphire substrate may be commonly used therefor. A sapphire substrate is formed of a crystal having Hexa-Rhombo R3C symmetry, and has a lattice constant of 13.001 Å along a C-axis and a lattice constant of 4.758 Å along an A-axis. Orientation planes of the sapphire substrate include a C (0001) plane, an A (1120) plane, an R (1102) plane, and the like. Here, the C plane is mainly used as a substrate for nitride growth because it relatively facilitates the growth of a nitride film and is stable at high temperature. In addition, a substrate formed of SiC, GaN, ZnO, MgAl₂O₄, MgO, LiAlO₂, LiGaO₂, or the like, may be used.

The buffer layer 120 is provided between the substrate 110 and the n-type semiconductor layer 130 to alleviate a lattice mismatch therebetween, thereby improving the crystalline quality of the nitride semiconductor single crystal grown on the substrate 110. The buffer layer 120 may be an AlN nucleation layer or a GaN nucleation layer grown at low temperature. Alternatively, the buffer layer 120 may be grown as an undoped GaN layer. In addition, the buffer layer 120 may be omitted as necessary.

The n-type and p-type semiconductor layers 130 and 160 may be formed of a nitride semiconductor, that is, a semiconductor material doped with n-type and p-type impurities having a composition expressed by AlₓIn_{y}Ga_{(1-x-y)N, where} 0≦x≦1, 0≦y≦1, 0≦x+y≦1. As representative semiconductor materials, GaN, AlGaN, and InGaN may be used. The n-type impurities may include Si, Ge, Se, Te and the like, and the p-type impurities may include Mg, Zn, Be and the like. The n-type and p-type semiconductor layers 130 and 160 may be grown by metal organic chemical vapor deposition (MOCVD), molecular beam epitaxy (MBE), hydride vapor phase epitaxy (HYPE), or the like.

The active layer 140 may emit light having a predetermined level of energy through electron-hole recombination and may be interposed between the n-type and p-type semiconductor layers 130 and 160. The active layer 140 may be formed on the n-type semiconductor layer 130 and have a structure in which one or more quantum well layers and one or more quantum barrier layers are alternately stacked. For example, the active layer 140 may have a multi-quantum well (MQW) structure in which InGaN quantum well layers and GaN quantum barrier layers are alternately stacked. The active layer 140 may be controlled in terms of wavelength and quantum efficiency by adjusting the height of quantum barrier layers, the thickness of quantum well layers, the composition, and the number of quantum well layers.

The electron blocking layer 150 may serve to prevent electrons having a relatively higher degree of mobility than holes from overflowing into the p-type semiconductor layer by passing through the active layer 140. To enable this, the electron blocking layer 150 may be formed of a material having an energy band gap higher than that of the active layer 140. The electron blocking layer 150 may block the overflow of the electrons to thereby increase electron-hole recombination;

however, the electron blocking layer 150 may also block the inflow of the holes, so that it may be difficult to achieve as satisfactory light emitting efficiency as expected. Therefore, according to the present embodiment, the electron blocking layer 150 may be provided to have a structure allowing for the electrons to avoid overflowing while reducing the blocking of the holes.

Specifically, as illustrated in FIG. 2, the electron blocking layer 150 according to the present embodiment may be formed on the active layer 140 and may have a multilayer superlattice structure including three layers 151, 153 and 155 having different energy band gaps. In this case, individual layers forming the electron blocking layer 150 may have a thickness allowing for carrier tunneling, preferably, within a range of 0.5 nm to 20 nm. A total thickness of the superlattice structure may range from 1 nm to 100 nm.

In addition, the electron blocking layer 150 may be formed to have different energy bands by appropriately adjusting energy band gaps of individual layers according to the content of aluminum or indium. A layer adjacent to the active layer 140 among the three layers 151, 153 and 155 may have an inclined energy band structure.

The multilayer structure of the electron blocking layer 150 may be formed to allow individual layers to have energy band gaps gradually decreasing in a stacking direction. That is, the electron blocking layer 150 may have the multilayer structure including a first layer 151 having an energy band gap higher than that of a quantum barrier layer that is the uppermost layer of the active layer 140, a third layer 155 having an energy band gap lower than that of the first layer 151, and a second layer 153 interposed between the first layer 151 and the third layer 155 and having an energy band gap between the energy band gaps of the first and third layers 151 and 155.

The first layer 151 may be formed to be adjacent to the quantum barrier layer of the active layer 140 and may have an energy band gap linearly increasing in the stacking direction. Due to such an inclined energy band structure of the first layer 151, the electron blocking layer 150 according to the present embodiment may alleviate spikes and notches occurring at an interface between the first and second layers 151 and 153, whereby hole injection efficiency into the active layer 140 may be increased. Accordingly, light emitting efficiency at high current density may be improved.

The multilayer structure of the electron blocking layer 150 may be formed of a material having a composition expressed by InₓAl_{y}Ga_{1-x-y}N, where 0≦x≦1, 0≦y≦1, 0≦x+y≦1. For example, the electron blocking layer 150 may have a sequentially stacked structure of AlGaN/GaN/InGaN layers formed on the active layer 140. Here, the first layer 151 may be formed of AlGaN, the second layer 153 may be formed of GaN, and the third layer 155 may be formed of InGaN. The inclined energy band structure of the first layer 151 may be formed by linearly decreasing Al components. In addition, the electron blocking layer 150 may have the stacked structure of the AlGaN/GaN/InGaN layers repetitively stacked at least one or more times.

Therefore, the electron blocking layer 150 may allow the first layer 151 having an energy band gap higher than that of the quantum barrier layer of the active layer 140 to prevent electrons introduced from the n-type semiconductor layer 130 from overflowing into the p-type semiconductor layer 160 by passing through the active layer 140. In addition, the electron blocking layer 150 may have a multilayer structure including layers having different energy band gaps, such that the spreading of holes due to differences in energy band gaps of individual layers included in the multilayer structure may be obtained, whereby hole injection from the p-type semiconductor layer 160 into the active layer 140 may be increased. In addition, the electron blocking layer 150 may be formed to have a superlattice structure, so that hole injection efficiency may be further improved.

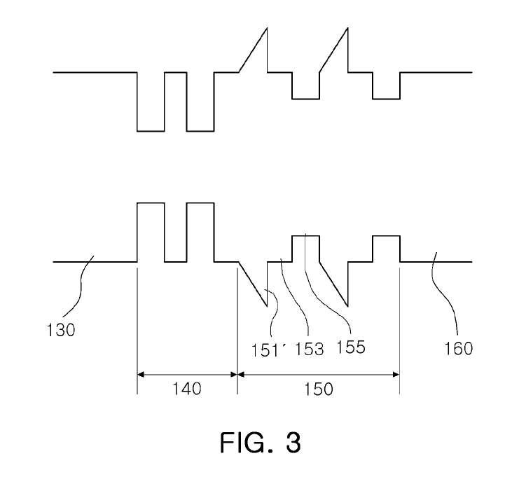

FIG. 3 is an energy band gap diagram of the semiconductor light emitting device of FIG. 1 including another example of an electron blocking layer. Here, the configuration of the semiconductor light emitting device of FIG. 3 is substantially the same as that of the semiconductor light emitting device of FIGS. 1 and 2, except that a direction of inclination of a first layer 151′ included in the electron blocking layer 150 is opposite to that of the first layer 151 illustrated in FIG. 2. Therefore, descriptions of the same features will be omitted and only different features will be described.

As illustrated in FIG. 3, the electron blocking layer 150 according to the present embodiment may be formed to be adjacent to the active layer 140. That is, the electron blocking layer 150 may have the multilayer structure including the first layer 151′ having an energy band gap higher than that of the quantum barrier layer that is the uppermost layer of the active layer 140, the third layer 155 having an energy band gap lower than that of the first layer 151′, and the second layer 153 interposed between the first layer 151′ and the third layer 155 and having an energy band gap between the energy band gaps of the first and third layers 151′ and 155. Here, the inclination of the energy band gap of the first layer 151′ may be linearly increased in the stacking direction.

That is, the electron blocking layer 150 according to the present embodiment may have the multilayer structure including the first layer 151′ formed of AlGaN, the second layer 153 formed of GaN, and the third layer 155 formed of InGaN. The inclined energy band structure of the first layer 151′ may be formed by linearly increasing Al components.

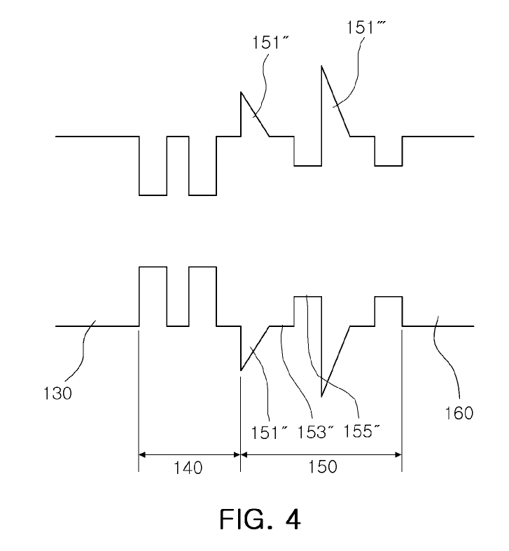

FIG. 4 is an energy band gap diagram of the semiconductor light emitting device of FIG. 1 including another example of an electron blocking layer. Here, the configuration of the semiconductor light emitting device of FIG. 4 is substantially the same as that of the semiconductor light emitting device of FIGS. 1 and 2, except that the electron blocking layer 150 has multilayer structures, each of which includes three layers, repetitively stacked at least one or more times, and first layers 151″ and 151′″ included in respective multilayer structures have energy band gaps obtained by adjusting the content of Al components to be different. Therefore, descriptions of the same features will be omitted and only different features will be described.

As illustrated in FIG. 4, the electron blocking layer 150 according to the present embodiment may be formed to be adjacent to the active layer 140 and may have the multilayer structures each including the first layer 151″ or 151″′ having an energy band gap higher than that of the quantum barrier layer that is the uppermost layer of the active layer 140, a third layer 155″ having an energy band gap lower than that of the first layer 151″, and a second layer 153″ interposed between the first layer 151″ or 151″′ and the third layer 155″ and having an energy band gap between the energy band gaps of the first layer 151″ or 151″′ and the third layer 155″

That is, the electron blocking layer 150 according to the present embodiment may have the multilayer structures each including the first layer 151″ or 151″' formed of AlGaN, the second layer 153″ formed of GaN, and the third layer 155″ formed of InGaN. In the case in which the electron blocking layer 150 has the multilayer structures repetitively stacked at least one or more times, the first layers 151″ and 151″′ may have energy band gaps increasing in a direction toward the p-type semiconductor layer 160 by increasing the content of Al components therein. In addition, although not illustrated, the first layers 151″ and 151″′ may have energy band gaps decreasing in a direction toward the p-type semiconductor layer 160 by decreasing the content of Al components therein.

FIG. 5 is a side cross-sectional view of a semiconductor light emitting device according to a second embodiment of the present disclosure. Here, the configuration of the semiconductor light emitting device of FIG. 5 is substantially the same as that of the semiconductor light emitting device of FIG. 1, except that a conductive substrate is used as a p-type electrode and an n-type electrode is formed on an n-type semiconductor layer after a growth substrate is removed. Therefore, descriptions of the same features will be omitted and only different features will be described.

As illustrated in FIG. 5, a semiconductor light emitting device 200 according to the second embodiment may include a conductive substrate 290, a p-type semiconductor layer 260, an electron blocking layer 250, an active layer 240, an n-type semiconductor layer 230 and an n-type electrode 270.

Here, the conductive substrate 290 may serve as the p-type electrode and as a support for the p-type semiconductor layer 260, the electron blocking layer 250, the active layer 240 and the n-type semiconductor layer 230 during a laser lift off (LLO) process and the like. That is, the growth substrate for semiconductor single crystals may be removed by the LLO process or the like, the n-type electrode 270 may be formed on a surface of the n-type semiconductor layer 230 exposed after the removal of the growth substrate. In this case, the conductive substrate may be formed of Si, Cu, Ni, Au, W, Ti or an alloy thereof, and may be formed by plating, bonding, or the like according to selected materials.

The electron blocking layer 250 according to the present embodiment may be formed to be adjacent to the active layer 240 and may have a multilayer structure including a first layer 251 having an energy band gap higher than that of a quantum barrier layer that is the uppermost layer of the active layer 240, a third layer 255 having an energy band gap lower than that of the first layer 251, and a second layer 253 interposed between the first layer 251 and the third layer 255 and having an energy band gap between the energy band gaps of the first and third layers 251 and 255.

The electron blocking layer 250 may have the multilayer structure including the first layer 251 formed of AlGaN, the second layer 253 formed of GaN, and the third layer 255 formed of InGaN, and such multilayer structures may be repetitively stacked. In this case, the repetitively stacked structures may form a superlattice structure.

Meanwhile, although not illustrated, a high reflective ohmic contact layer (not shown) able to perform ohmic contact and light reflective functions may be further formed between the p-type semiconductor layer 260 and the conductive substrate 290.

Therefore, the electron blocking layer 250 according to the present embodiment may allow the first layer 251 having an energy band gap higher than that of the quantum barrier layer of the active layer 240 to prevent electrons introduced from the n-type semiconductor layer 230 from overflowing into the p-type semiconductor layer 260 by passing through the active layer 240. In addition, the electron blocking layer 250 may have a multilayer structure including layers having different energy band gaps, such that the spreading of holes due to differences in energy band gaps of individual layers included in the multilayer structure may be obtained, whereby hole injection from the p-type semiconductor layer 260 into the active layer 240 may be increased. In addition, the electron blocking layer 250 may be formed to have a superlattice structure, so that hole injection efficiency may be further improved.

FIG. 6 is a graph illustrating simulation results in terms of light emitting efficiency of a semiconductor light emitting device according to an embodiment of the present disclosure and a semiconductor light emitting device including an electron blocking layer having a general superlattice structure. Here, the general superlattice structure may have AlGaN/GaN layers repetitively stacked therein.

In the semiconductor light emitting device according to the embodiment of the inventive concept, the electron blocking layer may have a sequentially stacked structure of AlGaN/GaN/InGaN layers, and a first layer formed of AlGaN may have an inclined energy band gap structure. Here, ‘B’ indicates a case in which Al components are gradually decreased, and ‘C’ indicates a case in which Al components are gradually increased. In addition, ‘A’ indicates a case of the semiconductor light emitting device including the electron blocking layer having a general superlattice structure.

As illustrated in FIG. 6, it could be appreciated that a reduction of light emitting efficiency according to an increase in current density is lowered in cases ‘B’ and ‘C’ rather than in case ‘A. ’ That is, it could be appreciated that cases ‘B’ and ‘C’ exhibit improved light emitting efficiency at high current density, and in the case in which Al components are gradually increased, light emitting efficiency is further improved.

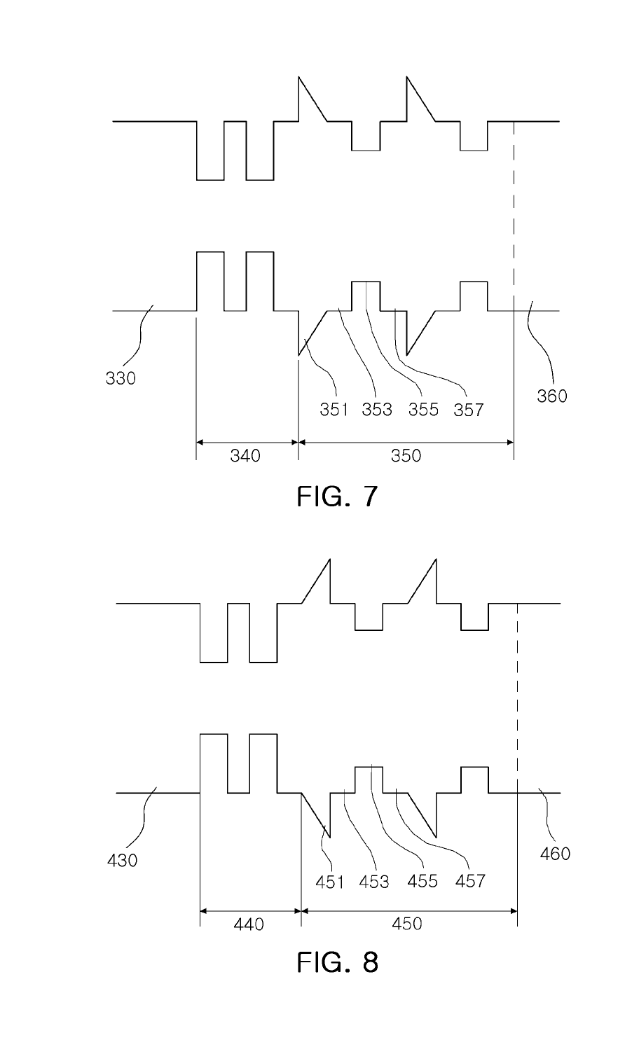

FIGS. 7 through 9 are energy band gap diagrams of semiconductor light emitting devices according to a third embodiment of the present disclosure. Here, the configurations of the semiconductor light emitting devices of FIGS. 7 through 9 are substantially the same as those of the semiconductor light emitting devices of FIGS. 1 through 4, except that an electron blocking layer includes four layers. Therefore, descriptions of the same features will be omitted and only different features will be described. The electron blocking layer adopted in FIGS. 7 through 9 may also be adopted in the semiconductor light emitting device having a vertical electrode structure illustrated in FIG. 5.

With reference to FIG. 7, an electron blocking layer 350 may be formed on an active layer 340 and may have a multilayer superlattice structure including four layers 351, 353, 355 and 357. In this case, individual layers forming the electron blocking layer 350 may have a thickness allowing for carrier tunneling, preferably, within a range of 0.5 nm to 20 nm. A total thickness of the superlattice structure may range from 1 nm to 100 nm.

The multilayer structure of the electron blocking layer 350 may be formed to allow individual layers to have energy band gaps gradually decreasing in a stacking direction. That is, the electron blocking layer 350 may have the multilayer structure including a first layer 351 having an energy band gap higher than that of a quantum barrier layer that is the uppermost layer of the active layer 340, a third layer 355 having an energy band gap lower than that of the first layer 351, a second layer 353 interposed between the first layer 351 and the third layer 355 and having an energy band gap between the energy band gaps of the first and third layers 351 and 355, and a fourth layer 357 having an energy band gap equal to that of the second layer 353 and formed on the third layer 355. In addition, the electron blocking layer 350 may have the multilayer structure repetitively stacked at least one or more times. When the multilayer structures are repetitively stacked, the fourth layer 357 may alleviate strain resulting from a lattice mismatch between the third layer 355 and the first layer 351.

The first layer 351 may be formed to be adjacent to the quantum barrier layer of the active layer and may have an energy band gap whose inclination is linearly increased in the stacking direction. Due to such an inclined energy band structure of the first layer 351, the electron blocking layer 350 according to the present embodiment may alleviate spikes and notches occurring at an interface between the first and second layers 351 and 353, whereby hole injection efficiency into the active layer 340 may be increased. Accordingly, light emitting efficiency at high current density may be improved.

The multilayer structure of the electron blocking layer 350 may be formed of a material having a composition expressed by InₓAl_{y}Ga_{1-x-y}N, where 0≦x≦1, 0≦y≦1, 0≦x+y≦1. For example, the electron blocking layer 350 may have a sequentially stacked structure of AlGaN/GaN/InGaN/GaN layers formed on the active layer 340. Here, the first layer 351 may be formed of AlGaN, the second layer 353 may be formed of GaN, the third layer 355 maybe formed of InGaN, and the fourth layer 357 may be formed of GaN. The inclined energy band structure of the first layer 351 may be formed by linearly decreasing Al components. In addition, the electron blocking layer 350 may have the stacked structure of the AlGaN/GaN/InGaN/GaN layers repetitively stacked at least one or more times. Here, the fourth layer 357 formed of GaN may alleviate strain resulting from a lattice mismatch between the third layer 355 formed of InGaN and the first layer 351 formed of AlGaN.

Therefore, the electron blocking layer 350 according to the present embodiment may allow the first layer 351 having an energy band gap higher than that of the quantum barrier layer of the active layer 340 to prevent electrons introduced from the n-type semiconductor layer 330 from overflowing into the p-type semiconductor layer 360 by passing through the active layer 340. In addition, the electron blocking layer 350 may have a multilayer structure including layers having different energy band gaps, such that the spreading of holes due to differences in energy band gaps of individual layers included in the multilayer structure may be obtained, whereby hole injection from the p-type semiconductor layer 360 into the active layer 340 may be increased. In addition, the electron blocking layer 350 may be formed to have a superlattice structure, so that hole injection efficiency may be further improved.

With reference to FIG. 8, an electron blocking layer 450. according to the present embodiment is different from the electron blocking layer 350 illustrated in FIG. 7, in that a direction of inclination of a first layer 451 included in the electron blocking layer 450 is opposite to that of the first layer 151 included in the electron blocking layer 350 of FIG. 7.

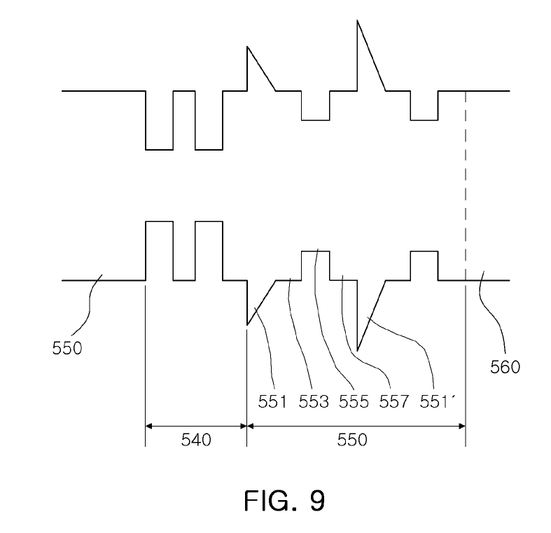

With reference to FIG. 9, an electron blocking layer 550 according to the present embodiment is different from the electron blocking layer 350 illustrated in FIG. 7, in that the electron blocking layer 550 has multilayer structures, each of which includes four layers, repetitively stacked at least one or more times, and first layers 551 and 551′ included in respective multilayer structures have energy band gaps obtained by adjusting the content of Al components to be different. That is, FIG. 9 illustrates that the first layers 551 and 551′ may have energy band gaps increasing in a direction toward the p-type semiconductor layer 560 by increasing the content of Al components therein. In addition, although not illustrated, the first layers 551 and 551′ may have energy band gaps decreasing in a direction toward the p-type semiconductor layer 560 by decreasing the content of Al components therein.

Meanwhile, according to the embodiments described herein, the inclination of the first layer included in the electron blocking layer is linearly increased or decreased by adjusting the content of Al components to be linearly varied. However, the inventive concept is not limited thereto, and the first layer may have an inclined structure two-dimensionally or multi-dimensionally increasing or decreasing by adjusting the content of Al components to be functionally varied.

While the present inventive concept has been shown and described in connection with the embodiments, it will be apparent to those skilled in the art that modifications and variations can be made without departing from the spirit and scope of the inventive concept as defined by the appended claims.

What is claimed is:

1. A semiconductor light emitting device comprising:
an n-type semiconductor layer;
an active layer formed on the n-type semiconductor layer and including at least one quantum well layer and at least one quantum barrier layer alternately stacked therein;
an electron blocking layer formed on the active layer and having at least one multilayer structure including three layers having different energy band gaps stacked therein, a layer adjacent to the active layer among the three layers having an inclined energy band structure; and
a p-type semiconductor layer formed on the electron-blocking layer.

2. The semiconductor light emitting device of claim 1, wherein the electron blocking layer is formed of a semiconductor material having a composition expressed by InₓAl_{y}Ga_{1-x-y}N, where 0≦x≦1, 0≦y≦1, 0≦x+y≦1, and the individual layers in the multilayer structure of the electron blocking layer have different energy band gaps by adjusting a ratio between Al and In.

3. The semiconductor light emitting device of claim 2, wherein the individual layers in the multilayer structure of the electron blocking layer are sequentially stacked to allow the energy band gaps thereof to be decreased in a stacking direction.

4. The semiconductor light emitting device of claim 3, wherein the electron blocking layer has a sequentially stacked structure of AlGaN/GaN/InGaN layers.

5. The semiconductor light emitting device of claim 4, wherein the electron blocking layer has the stacked structure of AlGaN/GaN/InGaN layers repetitively stacked therein.

6. The semiconductor light emitting device of claim 3, wherein the electron blocking layer has a sequentially stacked structure of AlGaN/GaN/InGaN/GaN layers.

7. The semiconductor light emitting device of claim 6, wherein the electron blocking layer has the stacked structure of AlGaN/GaN/InGaN/GaN layers repetitively stacked therein.

8. The semiconductor light emitting device of claim 1, wherein the electron blocking layer has a superlattice structure.

9. The semiconductor light emitting device of claim 8, wherein the individual layers of the electron blocking layer have a thickness of 0.5 nm to 20 nm.

10. The semiconductor light emitting device of claim 1, wherein the layer, adjacent to the active layer, among the three layers included in the multilayer structure of the electron blocking layer, has an energy band gap, an inclination of which is increased in a stacking direction.

11. The semiconductor light emitting device of claim 1, wherein the layer, adjacent to the active layer, among the three layers included in the multilayer structure of the electron blocking layer, has an energy band gap higher than that of the active layer, while allowing an inclination of the energy band gap to be decreased in a stacking direction.

12. The semiconductor light emitting device of claim 1, further comprising:
an insulating substrate formed on a lower surface of the n-type semiconductor layer;
an n-type electrode formed on the n-type semiconductor layer exposed by removing portions of the active layer and the p-type semiconductor layer; and
a p-type electrode formed on the p-type semiconductor layer.

13. The semiconductor light emitting device of claim 1, further comprising:
a conductive substrate formed on the p-type semiconductor layer; and
an n-type electrode formed on the n-type semiconductor layer.
